(19) United States
(12) Patent Application Publication
(10) Pub. No.: US 2021/0363627 A1
(43) Pub. Date: Nov. 25, 2021

(54) VACUUM PROCESSING SYSTEM AND METHOD OF OPERATING A VACUUM PROCESSING SYSTEM

(71) Applicant: Applied Materials, Inc., Santa Clara, CA (US)

(72) Inventors: Stefan BANGERT, Steinau (DE); Wolfgang BUSCHBECK, Hanau (DE); Thomas BERGER, Norheim (DE)

(21) Appl. No.: 16/342,826

(22) PCT Filed: Apr. 26, 2018
(86) PCT No.: PCT/EP2018/060741

§ 371 Date: Apr. 17, 2019

(51) Int. Cl. C23C 14/04; H01L 51/00; H01L 51/56; H01L 21/67

(52) U.S. Cl. CPC C23C 14/042; H01L 51/0011; H01L 21/67184; H01L 51/56; H01L 51/001

(57) ABSTRACT

A vacuum processing system for routing a carrier with a substrate is described. The system includes a first vacuum processing chamber for processing the substrate on the carrier; a vacuum buffer chamber providing a processing time delay for the substrate; a second vacuum processing chamber for masked deposition of a material layer on the substrate; and one or more transfer chambers for routing the carrier from the first vacuum chamber to the vacuum buffer chamber and for routing the carrier from the vacuum buffer chamber to the second vacuum chamber.

### TECHNICAL FIELD

Embodiments of the present disclosure relate to vacuum processing systems and methods of operating a vacuum processing system, particularly for depositing two, three or more different materials on a plurality of substrates. Embodiments particularly relate to vacuum processing systems and methods of operating a vacuum processing system, wherein substrates which are held by substrate carriers are transported in the vacuum processing system along a substrate transportation path, e.g. into various deposition modules and out of various deposition modules. Further, embodiments particularly relate to vacuum processing systems and methods of operating vacuum processing systems, wherein substrates are supported by substrate carriers in an essentially vertical orientation.

### BACKGROUND

Opto-electronic devices that make use of organic materials are becoming increasingly popular for a number of reasons. Many of the materials used to make such devices are relatively inexpensive, so organic opto-electronic devices have the potential for cost advantages over inorganic devices. The inherent properties of organic materials, such as flexibility, may be advantageous for applications such as for the deposition on flexible or inflexible substrates. Examples of organic opto-electronic devices include organic light emitting devices, organic displays, organic phototransistors, organic photovoltaic cells, and organic photodetectors.

The organic materials of OLED devices may have performance advantages over conventional materials. For example, the wavelength at which an organic emissive layer emits light may be readily tuned with appropriate dopants. OLED devices make use of thin organic films that emit light when a voltage is applied across the device. OLED devices are becoming an increasingly interesting technology for use in applications such as flat panel displays, illumination, and backlighting.

Materials, particularly organic materials, are typically deposited on a substrate in a vacuum processing system under sub-atmospheric pressure. During deposition, a mask device may be arranged in front of the substrate, wherein the mask device may have at least one opening or a plurality of openings that define an opening pattern corresponding to a material pattern to be deposited on the substrate, e.g. by evaporation. The substrate is typically arranged behind the mask device during the deposition and is aligned relative to the mask device. Masking with an accuracy corresponding to a pixel resolution of a display is challenging, particularly for large area substrates and substantially vertical substrate orientation.

Typically, five or more or even ten or more material layers may subsequently be deposited on a substrate, e.g. for manufacturing a color display. Typically, one or more layers of organic material as well as one or more layers of metallic material are deposited in a layer stack. Particularly the precision of metallic layers may result in a substrate temperature increase, which adds further difficulty to accurate mask alignment, for example, for subsequently deposited layers. The desire to increase the throughput and, thus, reduce the tact time of the vacuum processing system adds further challenges.

Accordingly, it would be beneficial to provide an improved vacuum processing system and a method of operating an improved vacuum processing system for the deposition of materials on a plurality of substrates.

### SUMMARY

In light of the above, a vacuum processing system for processing a substrate, a vacuum processing system for depositing a plurality of layers on a substrate, and a method of operating a vacuum processing system are provided.

According to one embodiments, a vacuum processing system for routing a carrier with a substrate is provided. The system includes a first vacuum processing chamber for processing the substrate on the carrier; a vacuum buffer chamber providing a processing time delay for the substrate; a second vacuum processing chamber for masked deposition of a material layer on the substrate; and one or more transfer chambers for routing the carrier from the first vacuum chamber to the vacuum buffer chamber and for routing the carrier from the vacuum buffer chamber to the second vacuum chamber.

According to another embodiments, a vacuum processing system for OLED display manufacturing on a large area substrate is provided. The system includes a metal deposition chamber having an evaporator for metallic material to be deposited on a layer stack on the large area substrate; a vacuum buffer chamber provided downstream of the metal deposition chamber in the vacuum processing system, the vacuum buffer chamber configured to store two or more carriers supporting large area substrates; a further deposition chamber downstream of the vacuum buffer chamber and having a further evaporator to deposit a material on the large area substrate, the further deposition chamber including a mask support for a shadow mask masking the large area substrates to deposit the material on regions corresponding to the display pixels; and a transfer chamber including a cooling assembly arranged adjacent to a carrier position to reduce the temperature of the carrier.

According to another embodiments, a method of operating a vacuum processing system is provided. The method includes depositing a material layer on a substrate during a first tact time period; parking a carrier supporting the substrate in a vacuum buffer chamber during one or more second time periods subsequent to the first tact time period; and cooling the carrier in a transfer chamber adjacent to a cooling assembly during at least a portion of a third tact time period subsequent to the one or more second tact time periods.

Further aspects, advantages and features of the present disclosure are apparent from the description and the accompanying drawings.

### BRIEF DESCRIPTION OF THE DRAWINGS

So that the manner in which the above recited features of the present disclosure can be understood in detail, a more particular description of the present disclosure, briefly summarized above, may be had by reference to embodiments. The accompanying drawings relate to embodiments of the disclosure and are described in the following. Typical embodiments are depicted in the drawings and are detailed in the description which follows.

FIG. 1A illustrates a graph showing the temperature of the glass substrate after metal deposition;

FIG. 1B illustrates a graph showing the temperature of a carrier, for example, an electrostatic chuck over time;

FIG. 2 shows a portion of the vacuum processing system according to embodiments of the present disclosure, wherein a buffer chamber providing, for example, a first-in-first-out buffer for processed substrates, and a transfer chamber are shown;

FIG. 3 illustrates a graph showing the temperature of the substrate and the temperature of a carrier for a vacuum processing system according to embodiments of the present disclosure;

FIG. 4 shows an embodiment of a cooling assembly in a transfer chamber according to embodiments of the present disclosure;

FIG. 5 shows a cooling assembly according to embodiments of the present disclosure;

FIG. 6A shows a schematic view of a vacuum processing system according to embodiments of the present disclosure having two or more vacuum cluster chambers and a plurality of processing chambers connected to one or more of the vacuum cluster chambers;

FIG. 6B shows a schematic view of the vacuum processing system of FIG. 3A and illustrates an exemplary substrate traffic or flow of substrates within the vacuum processing system according to embodiments of the present disclosure;

FIG. 7A shows a schematic view of a further vacuum processing system according to embodiments of the present disclosure having two or more vacuum cluster chambers and a plurality of processing chambers connected to one or more of the vacuum cluster chambers;

FIG. 7B shows a schematic view of the vacuum processing system of FIG. 4A and illustrates an exemplary substrate traffic or flow of substrates within the vacuum processing system according to embodiments of the present disclosure;

FIG. 8 shows a schematic top view of an evaporation source assembly according to embodiments of the present disclosure; and

FIG. 9 shows a flow chart illustrating embodiments of methods of operating a vacuum processing system.

### DETAILED DESCRIPTION OF EMBODIMENTS

Reference will now be made in detail to the various embodiments, one or more examples of which are illustrated in the figures. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, same reference numbers may refer to the same or to similar components. Generally, only the differences with respect to the individual embodiments are described. Unless specified otherwise, the description of a part or aspect in one embodiment applies to a corresponding part or aspect in another embodiment as well.

OLED devices, such as OLED flat panel displays, may include a plurality of layers. For example, a combination of five or more, or even 10 or more layers may be provided. Typically, organic layers and metallic layers are deposited on a backplane, wherein the backplane may include a TFT structure. Particularly the organic layers may be sensitive to a gas environment (for example atmosphere) before encapsulation. Accordingly, it is beneficial to produce an entire layer stack including both, organic layers and metallic layers, within a vacuum processing system.

In the present disclosure, reference is made to manufacturing of an OLED flat-panel display, particularly for mobile devices. However, similar consideration, examples, embodiments and aspects may also be provided for other substrate processing applications. For the example of an OLED mobile display, a common metal mask (CMM) is provided in some processing chambers. The CMM provides an edge exclusion mask for each mobile display. Each mobile display is masked with one opening and areas on the substrate corresponding to areas between displays are mainly covered by the CMM. Other layers may be deposited with a fine metal mask (FFM). The fine metal mask has a plurality of openings, for example, sized in the micron range. The plurality of fine openings correspond to a pixel of the mobile display or the color of a pixel of the mobile display. Accordingly, the FFM and the substrate needs to be highly accurately aligned with respect to each other to have an alignment of the pixels on the display in a micron range. The combination of large area substrates, vertical substrate orientation and the resulting gravity force, as well as thermal expansion due to thermal impact of, for example, evaporation processes make an accurate mask alignment challenging.

According to some embodiments of the present disclosure, a substrate may be held at a substrate carrier by a chucking device, e.g. by an electrostatic chuck and/or by a magnetic chuck. Other types of chucking devices may be used. Typically, the substrate carrier includes a carrier body and a substrate receiving plate. The substrate is held at the substrate receiving plate by, for example, an electrostatic force and/or a magnetic force. “Transporting”, “moving”, “routing”, “replacing” or “rotating” a substrate as used herein may refer to a respective movement of a carrier which holds the substrate in an orientation, particularly in a non-horizontal orientation, more particularly in an essentially vertical orientation.

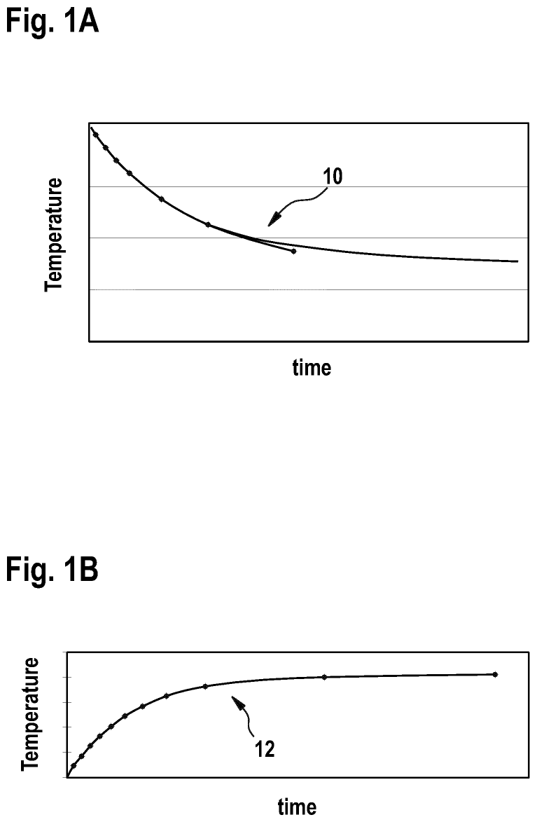

FIG. 1A illustrates a graph 10 showing the temperature of a glass substrate supported by a carrier after depositing a metal layer, for example, with a metal evaporator. It can be seen that the substrate temperature is elevated, for example, by at least 30 K after the metal deposition. The substrate temperature decreases with time, for example, after 10 to 20 minutes. Yet, on a longer timescale (several hours) the temperature of a carrier increases during operation of the vacuum processing system as shown in graph 12 in FIG. 1B. Evaluating the temperatures in the system, it may be found that the cooling of the substrate due to radiation is not significant. Further, due to the vacuum atmosphere in the vacuum processing system, heat exchange due to convection is also not significant. It has been found that the cooling of the substrate is mainly provided due to conduction, i.e. heat conduction, from the substrate to the substrate carrier. As shown in FIG. 1B, this process may suffer on a longer timescale (several hours to several 10 hours) as the substrate carrier temperature increases.

According to embodiments of the present disclosure, a vacuum processing system for routing a carrier with a substrate to be processed is provided. The system includes a first vacuum processing chamber for processing the substrate on the carrier, a vacuum buffer chamber providing a processing time delay for the substrate, a second vacuum processing chamber for masked deposition of a material layer on the substrate, and one or more transfer chambers for routing the carrier from the first vacuum chamber to the vacuum buffer chamber and for routing the carrier from the vacuum buffer chamber to the second vacuum chamber.

Providing a buffer chamber introducing a processing time delay reduces alignment accuracy issues for deposition, for example, with a fine metal mask (FFM) after the metal deposition that may increase the substrate temperature by 30 K or more, such as even 50 K or more. For example, according to some embodiments, which can be combined with other embodiments described herein, metal deposition may be provided with the CMM that may further increase the heat load on the substrate. A vacuum buffer chamber according to embodiments of the present disclosure allows to have a substrate temperature that is sufficiently low for a subsequent (downstream) FMM deposition process, wherein, for example, a high alignment accuracy of the fine metal mask is beneficial.

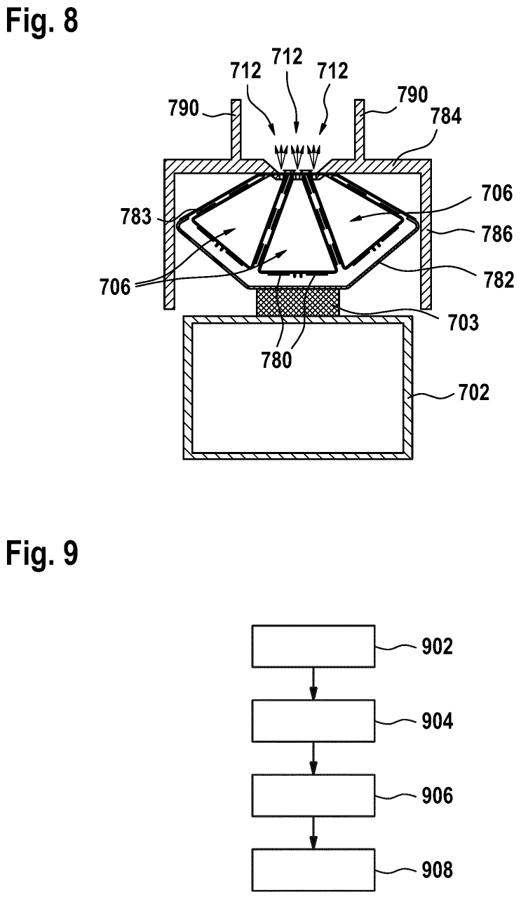

According to embodiments of the present disclosure, which can be combined with other embodiments, one or more of several aspects may be used independently or beneficially in combination for substrate temperature management. An improved substrate temperature management allows, in turn, for an improved alignment accuracy of a mask, particularly a mask having openings corresponding to pixels of a display. According to one aspect, the heat load on the substrate of an evaporation source can be reduced or minimized. This will be described in more detail with respect to FIG. 8. According to another aspect, the mass of the carrier can be used as a heat buffer to minimize temperature increase of the substrate and to allow improved heat conduction in a buffer chamber. Accordingly, according to some embodiments, which can be combined with other embodiments described herein, the thickness of the carrier can be 8 mm or above, such as 15 mm or above. Considering a roughly similar area of the substrate carrier and the substrate, particularly in light of the fact that large area substrates can be used according to some embodiments, the carrier thickness is large as compared to the substrate thickness of 1 mm or below, such as about 0.5 mm. According to yet another aspect, an active radiation cooling can be provided, particularly for the substrate carrier and/or after heat conductance from the substrate to the substrate carrier has occurred.

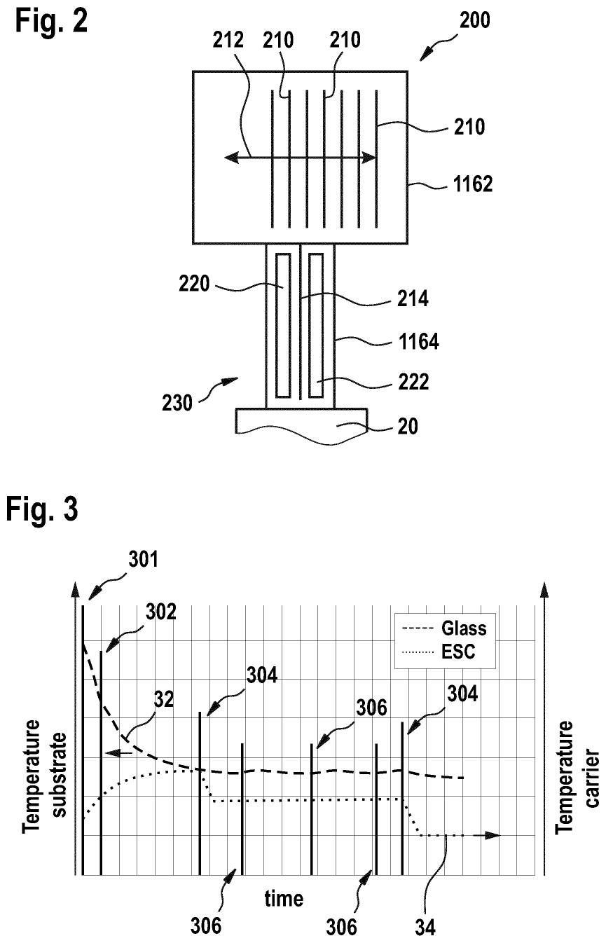

As shown in FIG. 2, the vacuum buffer chamber 1162 can be provided. According to embodiments of the present disclosure, the vacuum buffer chamber 1162 is configured to provide a processing time delay. The vacuum buffer chamber 1162 can be a cooling area 200. According to some embodiments, which can be combined with other embodiments described herein, the vacuum buffer chamber can provide the first-in-first-out stack for received carriers supporting respective substrates. Additionally or alternatively, the vacuum buffer chamber can be configured to buffer four or more substrate carriers. Accordingly, a processing time delay can be at least four times the tact time of the vacuum processing system.

According to some embodiments, which can be combined with other embodiments described herein, a method of operating a vacuum processing system can include the introduction of a wait time of at least four times the tact time of the vacuum processing system.

For example, FIG. 2 shows seven substrate carrier slots 210 that may store a substrate carrier having a substrate. As indicated by arrow 212, substrate carrier slots 210 or the array of substrate carrier slots can be moved in order to align a substrate carrier slot 210 with a transportation path 214 of an adjacent transfer chamber 1164. The substrate carrier can be transported through the transfer chamber 1164 along the transportation path 214 on a substrate carrier slot 210 of the vacuum buffer chamber 1162. For example, the substrate may be transported to or from an adjacent vacuum chamber 20, e.g. a vacuum cluster chamber. The movement of the substrate carrier slots 210 allows to operate the substrate carrier buffer as a first-in-first-out buffer (FIFO buffer). A FIFO buffer allows for constant substrate processing delay times for subsequence substrates.

FIG. 2 further illustrates a cooling assembly 230, which may be provided in some embodiments. The cooling assembly 230 is provided in the transfer chamber 1164. Accordingly, a carrier, having a substrate, having experienced the processing delay time in the vacuum buffer chamber 1162, during which the temperature of the carrier increases, can be cooled with the cooling assembly. For example, the cooling assembly can include a cooling unit 220 at the backside of the substrate carrier and, optionally, a cooling unit 222 at the front side of the substrate carrier. Typically, the front side of the substrate carrier is the side supporting the substrate.

According to embodiments of the present disclosure, which can be combined with other embodiments described herein, a cooling element of the cooling unit can be a cryo-cooler, a cryo-generator, a cryo-gas-chiller, or the like. The cooling unit may cool compressed dry gases such as nitrogen, organ or air. For example, gas can be cooled from an ambient temperature to a cryogenic temperature of −80° C. or below, such as −100° C. or below.

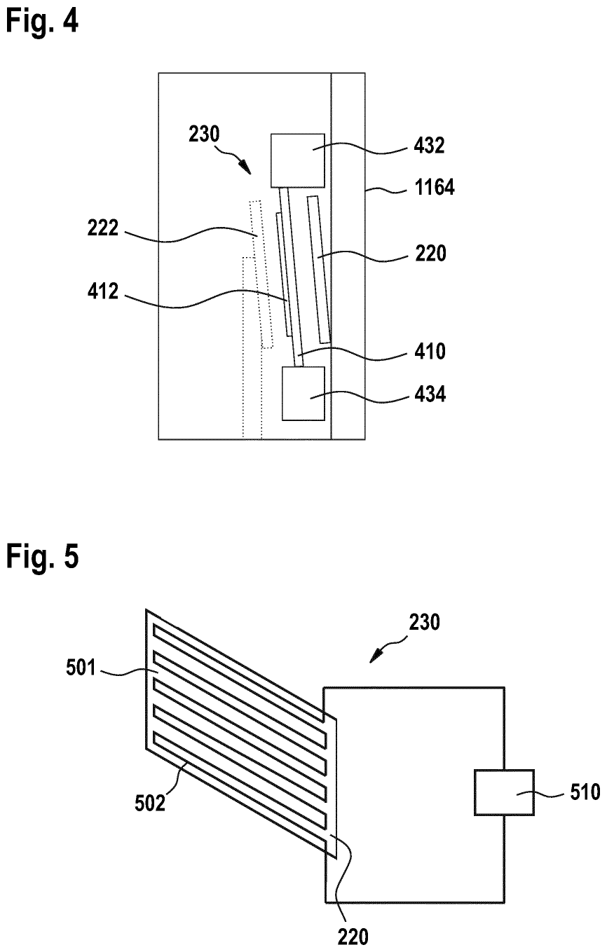

According to embodiments of the present disclosure, which can be combined with other embodiments described herein, a cooling assembly 230 can be provided adjacent to a carrier position, particularly a carrier position in the transfer chamber 1164. Further details are described with respect to FIGS. 4 and 5. Yet further, according to some alternative or additional modifications, the cooling assembly 230 may include one or more cooled surfaces having an area with conduits for cooling fluid, for example a cooling gas.

FIG. 3 shows exemplarily the temperature of the substrate (see graph 32 having dashed lines) and the temperature of a carrier (see graph 34 having dotted lines) evolving over time according to embodiments of the present disclosure, i.e. for vacuum processing systems according to embodiments of the present disclosure, and a method of operating a vacuum processing system according to the present disclosure.

An embodiment of operating a vacuum processing system may include depositing the material layer, for example, a metallic layer, on a substrate during the first tact time period.

The substrate traffic can be described for a plurality of substrates, which are simultaneously processed in a vacuum processing system. For simultaneous processing, tact time is typically provided such that the processing of the substrate, the transportation of the substrate in the system and other operating conditions are synchronized. According to some embodiments, which can be combined with other embodiments described herein, a tact time of the system, i.e. a time period, can be 180 seconds or below, e.g. from 60 seconds to 180 seconds. For example, the substrate is processed within this time period, i.e. a first exemplary time period T.

The graph shown in FIG. 3 starts at time 301 after depositing the material layer. The carrier supporting the substrate can be moved to the vacuum buffer chamber, for example, during tact time. The carrier supporting the substrate is, according to embodiments of the present disclosure, parked in the vacuum buffer chamber, for example at time 302.

The carrier is parked for one or more tact time periods until about time 304. For example, the carrier supporting the substrate can be parked for three or more tact times. According to embodiments, which can be combined with other embodiments described herein, the vacuum buffer chamber can be provided and/or operated as a FIFO buffer. During that time, the substrate temperature decreases and the carrier temperature increases. The carrier can be used as a heat buffer for the substrate.

The carrier can be moved to a cooling assembly, for example, a cooling assembly provided in a transfer chamber. At time 304 the carrier can be called with the cooling assembly during a portion of a further tact time. As shown in FIG. 3 by graph 34, the temperature of the carrier decreases. Subsequently, as indicated by time 306 in FIG. 3, deposition can be provided on the substrate, for example, deposition of organic materials with a fine metal mask. For the masked deposition of, for example, organic material, the substrate temperature has sufficiently been reduced, as shown by graph 32, to allow for improved mask alignment relative to the substrate.

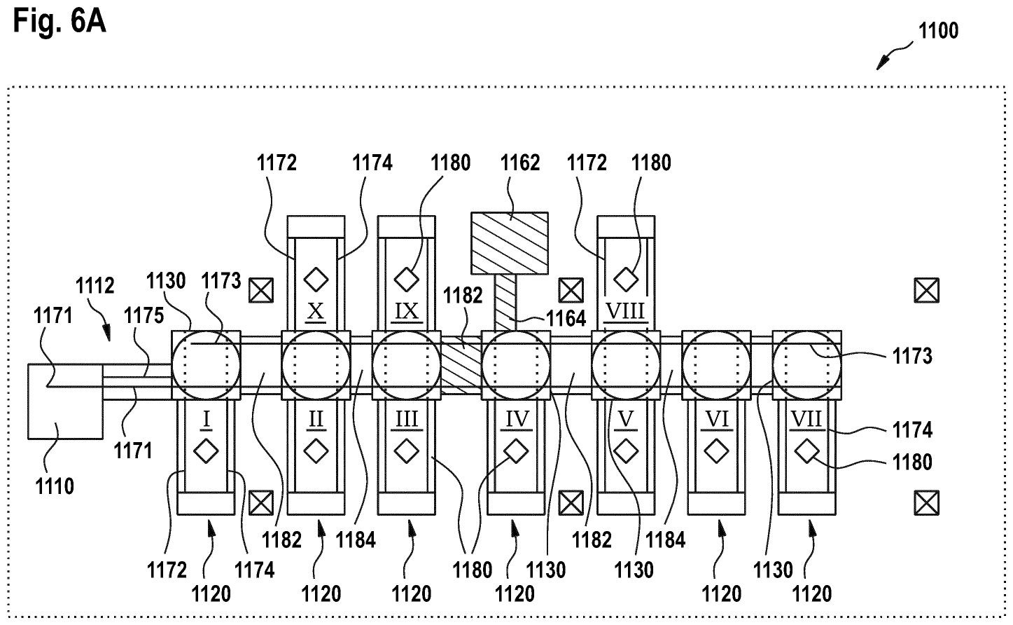

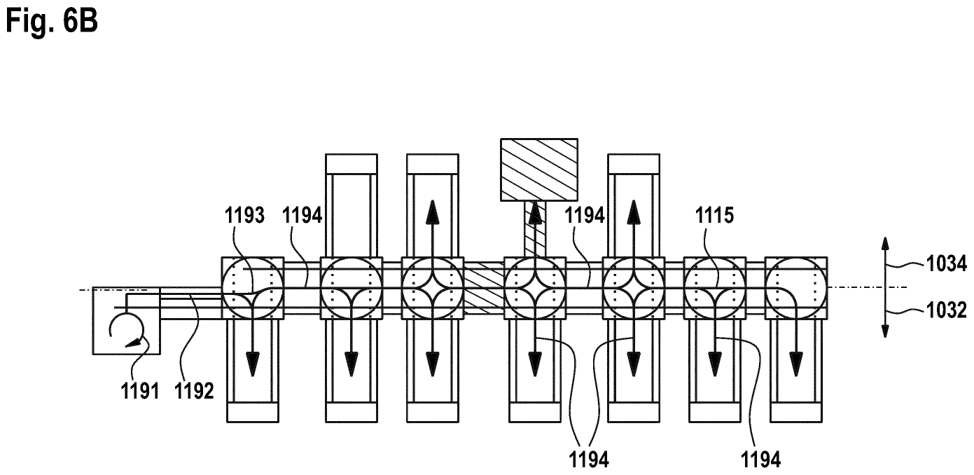

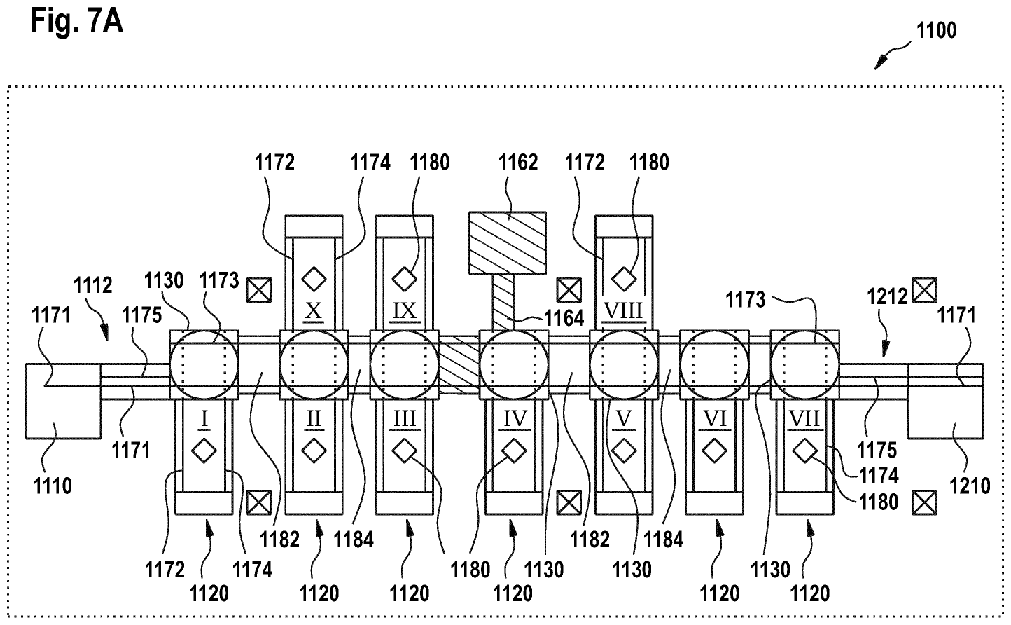

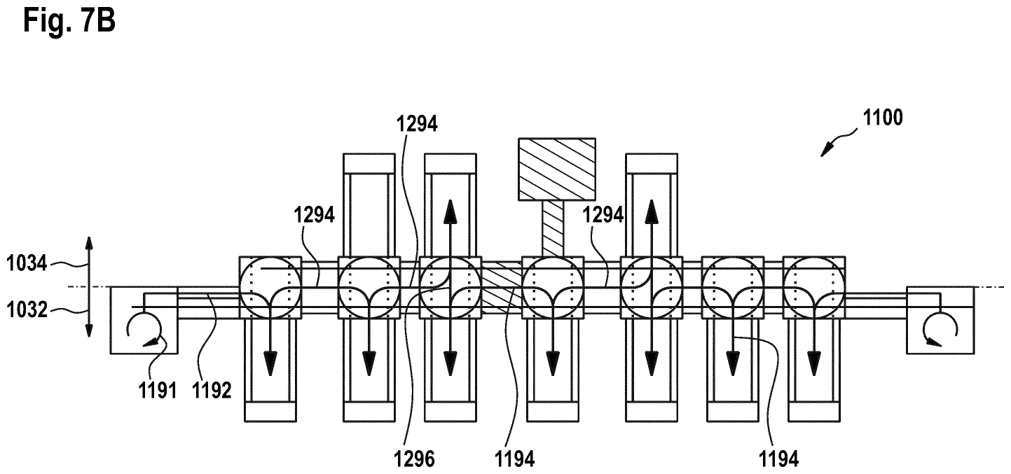

According to yet further embodiments, a second cooling assembly can be provided in the vacuum processing system. For example, the second cooling assembly can be provided in further transfer chambers of the vacuum processing system, as described with respect to FIGS. 6A and 7A. This is illustrated in FIG. 3 by the second time 304 after which a further decrease of the substrate carrier temperature starts. Accordingly, the substrate carrier temperature can be reduced to about 30° C. or below. According to some embodiments, which can be combined with other embodiments described herein, a vacuum processing system may have one, two, three, four or more cooling assemblies, such as cooling assembly provided in a transfer chamber. For example, two cooling assemblies may be provided.

FIG. 4 illustrates a transfer chamber 1164 of one or more transfer chambers of the vacuum processing system according to embodiments described herein. For example, the transfer chamber 1164 can be provided between the vacuum buffer chamber and a further vacuum chamber of the system. Exemplarily, further vacuum chambers can be a cluster chamber such as a vacuum rotation chamber (see, for example, vacuum rotation chambers 1130 in FIG. 6 A).

The transfer chamber 1164 is a vacuum chamber and may include a magnetic levitation system having a magnetic levitation box 432 and a magnetic drive box 434. The carrier 410 can be arranged in the vacuum chamber, for example, while being levitated. According to some embodiments, which can be combined with other embodiments described herein, the carrier 410 is arranged adjacent to a cooling assembly 230, for example, a cooling unit 220 of the cooling assembly. According to some embodiments, a cooling unit 220 can be provided on the backside of the substrate carrier 410, i.e. the side of the carrier opposite to the side at which the substrate 412 is mounted.

According to some embodiments, optionally, a second cooling unit 222 can be provided at the front side of the substrate carrier 410, i.e. facing the substrate 412.

FIG. 5 illustrates a cooling assembly 230 according to embodiments of the present disclosure in more detail. A cooling unit 220 of the cooling assembly can include a plate 501. A plurality of conduits 502 can be provided at the plate 501. For example the conduits 502 can be attached to the plate or embedded in the plate. The conduits 502 are in fluid communication with each other and provide, for example, a closed loop with the cooling element 510 for a cooling fluid. A cooling element of the cooling unit can be a cryo-cooler, a cryo-generator, a cryo-gas-chiller, or the like. The cooling fluid is cooled in the cooling element 510 and the cooling fluid is circulated through the conduits 502. Accordingly, the conduits and the plate 501 can be cooled to a temperature of minus 50° C. or below, such as minus 100° C. or below. The cooling unit 220 provided adjacent to the carrier 410 can cool the carrier, for example, while the carrier is parked next to the cooling assembly. Accordingly, the temperature of the carrier can be decreased. The heat energy that has previously been absorbed by the carrier from the substrate can be transferred by heat radiation to the cooling fluid.

As described above, the vacuum processing system may include one or more transfer chambers. An exemplary vacuum processing system 1100 is shown in FIG. 6A. The vacuum processing system shown in FIG. 6A includes a plurality of vacuum cluster chambers, a plurality of processing chambers, and a plurality of transfer chambers. According to one embodiment, which can be combined with other embodiments described herein, the one or more transfer chambers referred to herein can include a first vacuum cluster chamber directing a carrier from a first transport direction in the vacuum processing system to a second transport direction in the vacuum processing system. Further, the vacuum processing system may include at least a second vacuum cluster chamber directing a carrier from a first transport direction in the vacuum processing system to a second transport direction in the vacuum processing system.

FIG. 6A shows a vacuum processing system 1100 according to embodiments of the present disclosure. The vacuum processing system 1100 provides a combination of a cluster arrangement and an in-line arrangement. A plurality of processing chambers 1120 are provided. The processing chambers 1120 can be connected to vacuum rotation chambers 1130. The vacuum rotation chambers 1130 are provided in an in-line arrangement. The vacuum rotation chambers 1130 can rotate substrates to be moved into and out of processing chambers 1120. The combination of a cluster arrangement and an in-line arrangement can be considered a hybrid arrangement. A vacuum processing system 1100 having a hybrid arrangement allows for a plurality of processing chambers 1120. The length of the vacuum processing system does still not exceed a certain limit.

According to embodiments of the present disclosure, a cluster chamber or a vacuum cluster chamber is a chamber, e.g. a transfer chamber, configured to have two or more processing chambers connected thereto. Accordingly, the vacuum rotation chambers 1130 are examples of a cluster chamber. Cluster chambers can be provided in an in-line arrangement in the hybrid arrangement.

A vacuum rotation chamber or a rotation module (also referred to herein as “routing module” or “routing chamber”) may be understood as a vacuum chamber configured for changing the transport direction of the one or more carriers may be changed by rotating one or more carriers located on tracks in the rotation module. For example, the vacuum rotation chamber may include a rotation device configured for rotating tracks configured for supporting carriers around a rotation axis, e.g. a vertical rotation axis. In some embodiments, the rotation module includes at least two tracks which may be rotated around a rotation axis. A first track, particularly a first substrate carrier track, may be arranged on a first side of the rotation axis, and a second track, particularly a second substrate carrier track, may be arranged on a second side of the rotation axis.

In some embodiments, the rotation module includes four tracks, particularly two mask carrier tracks and two substrate carrier tracks which may be rotated around the rotation axis.

When a rotation module rotates by an angle of x°, e.g. 90°, a transport direction of one or more carriers arranged on the tracks may be changed by an angle of x°, e.g. 90°. A rotation of the rotation module by an angle of 180° may correspond to a track switch, i.e. the position of the first substrate carrier track of the rotation module and the position of the second substrate carrier track of the rotation module may be exchanged or swapped and/or the position of the first mask carrier track of the rotation module and the position of the second mask carrier track of the rotation module may be exchanged or swapped. According to some embodiments, the rotation module may include a rotor on which a substrate can be rotated.

FIG. 6A shows the vacuum processing system 1100 and FIG. 6B illustrates the substrate traffic in the vacuum processing system. The substrate enters the vacuum processing system 1100, for example, at a vacuum swing module 1110. According to further modifications, a load lock chamber may be connected to the vacuum swing module for loading and unloading substrates into the vacuum processing system. The vacuum swing module typically receives the substrate directly or via a load lock chamber from an interface of the device manufacturing factory. Typically, the interface provides the substrate, for example, a large area substrate, in a horizontal orientation. The vacuum swing module moves the substrate from the orientation provided by the factory interface to an essentially vertical orientation. The essentially vertical orientation of the substrate is maintained during processing of the substrate in the vacuum processing system 1100 until the substrate is moved, for example, back to a horizontal orientation. Swinging, moving by an angle, or rotating the substrate is illustrated by arrow 1191 in FIG. 6B.

According to embodiments of the present disclosure, a vacuum swing module may be a vacuum chamber for movement from a first substrate orientation to a second substrate orientation. For example, the first substrate orientation can be a non-vertical orientation, such as a horizontal orientation, and the second substrate orientation can be a non-horizontal orientation, such as a vertical orientation or an essentially vertical orientation. According to some embodiments, which can be combined with other embodiments described herein, the vacuum swing module can be a substrate repositioning chamber configured to selectively position a substrate therein in a first orientation with respect to a horizontal orientation and a second orientation with respect to a horizontal orientation.

The substrate is moved through a buffer chamber 1112 (see FIG. 6A), for example as indicated by arrow 1192. The substrate is further moved through a cluster chamber, such as a vacuum rotation chamber 1130 into a processing chamber 1120. In some embodiments described with respect to FIGS. 6A and 6B, the substrate is moved into the processing chamber 1120-I. For example, a hole inspection layer (HIL) can be deposited on the substrate in the processing chamber 1120-I.

Subsequently, the substrate is moved out of the processing chamber 1120 into the adjacent cluster chamber, for example, vacuum rotation chamber 1130, through a first transfer chamber 1182, through a further cluster chamber, and into the processing chamber 1120-II. This is indicated by arrow 1194 in FIG. 6B. In processing chamber 1120-II, a hole transfer layer (HTL) is deposited on the substrate. Similarly to the hole injection layer, the hole transfer layer may be manufactured with a common metal mask having one opening per mobile display. Further, the substrate is moved out of the processing chamber 1120-II into the adjacent cluster chamber, for example, vacuum rotation chamber 1130, through a second transfer chamber 1184, through a further cluster chamber, and into the processing chamber 1120-III. This is indicated by further arrow 1194 in FIG. 6B.

A transfer chamber or transit module may be understood as a vacuum module or vacuum chamber that can be inserted between at least two other vacuum modules or vacuum chambers, e.g. between vacuum rotation chambers. Carriers, e.g. mask carriers and/or substrate carriers, can be transported through the transfer chamber in a length direction of the transfer chamber. The length direction of the transfer chamber may correspond to the main transportation direction of the vacuum processing system, i.e. the in-line arrangement of the cluster chambers.

In processing chamber 1120-111 an electron blocking layer (EB) is deposited on the substrate. The electron blocking layer can be deposited with a fine metal mask (FFM). The fine metal mask has a plurality of openings, for example, sized in the micron range. The plurality of fine openings correspond to a pixel of the mobile display or the color of a pixel of the mobile display. Accordingly, the FFM and the substrate need to be highly accurately aligned with respect to each other to have an alignment of the pixels on the display in a micron range.

The substrate is moved from processing chamber 1120-III, to processing chamber 1120-IV, subsequently to processing chamber 1120-V and to processing chamber 1120-VI. For each of the transportation paths, for example, two substrate transportation paths, the substrate is moved out of processing chamber into, for example, a vacuum rotation chamber, through a transfer chamber, through a vacuum rotation chamber and into the next processing chamber. For example, an OLED layer for red pixels can be deposited in chamber 1120-IV, an OLED layer for green pixels can be deposited in chamber 1120-V, and an OLED layer for blue pixels can be deposited in chamber 1120-VI. Each of the layers for color pixels are deposited with the fine metal mask. The respective fine metal masks are different such that the pixel dots of different color are adjacent to each other on the substrate to give the appearance of one pixel. As indicated by further arrow 1194 extending from processing chamber 1120-VI to processing chamber 1120-VII, the substrate can be moved out of the processing chamber into a cluster chamber through a transfer chamber through a further cluster chamber and into the subsequent processing chamber. In processing chamber 1120-VII, and electron transfer layer (ETL) may be deposited with the common metal mask (CMM).

The substrate traffic described above for one substrate is similar for a plurality of substrates, which are simultaneously processed in the vacuum processing system 1100. According to some embodiments, which can be combined with other embodiments described herein, a tact time of the system, i.e. a time period, can be 180 seconds or below, e.g. from 60 seconds to 180 seconds. Accordingly, the substrate is processed within this time period, i.e. a first exemplary time period T. In the processing chambers described above and the subsequent processing chambers described below, one substrate is processed within the first time period T, another substrate that has just been processed is moved out of the processing chamber within the first time period T, and yet a further substrate to be processed is moved into the processing chamber within the first time period T. One substrate can be processed in each of the processing chambers while two further substrates participate in substrate traffic with respect to this processing chamber, i.e. one further substrate is unloaded from the respective processing chamber and one substrate is loaded into the respective processing chamber during the first time period T.

The above described route of an exemplary substrate from processing chamber 1120-1 to processing chamber 1120-VII is provided in a row of processing chambers of the vacuum processing system 1100, for example, the lower row in FIGS. 6A and 6B. The row or lower part of the vacuum processing system is indicated by arrow 1032 in FIG. 6B.

According to some embodiments, which can be combined with other embodiments described herein, substrates can be routed in one row or one part of the vacuum processing system from one end of the in-line arrangement of cluster chambers to the opposing end of the in-line arrangement of cluster chambers of the vacuum processing system. At the opposing end of the in-line arrangement, for example, the vacuum rotation chamber 1130 at the right hand side in FIG. 6A, the substrate is transferred to the other row or the other part of the vacuum processing system. This is indicated by arrow 1115 in FIG. 6B. On the other row or in the other part of the vacuum processing system, which is indicated by arrow 1034 in FIG. 6B, the substrate is processed in subsequent processing chambers while moving from the opposing end of the in-line arrangement of cluster chambers to the one end, i.e. the starting end, of the in-line arrangement of cluster chambers.

In the example shown in FIG. 6A, the exemplary substrate is moved to processing chamber 1120-VIII, and subsequently to processing chamber 1120-IX. For example, a metallization layer, which can exemplarily form a cathode of the OLED device, can be deposited in processing chamber 1120-VIII, for example with a common metal mask as described above. For example, one or more of the following metals may be deposited in some of the deposition modules: Al, Au, Ag, Cu. At least one material may be a transparent conductive oxide material, e.g. ITO. At least one material may be a transparent material. Particularly in a metallization chamber, such as processing chamber 1120-VIII, the heat load on the substrate and, thus, the temperature increase of the substrate may be high. Accordingly, cooling according to embodiments of the present invention may beneficially be provided subsequent to such metal deposition.

FIG. 6A shows the vacuum buffer chamber 1162 and the transfer chamber 1164. The transfer chamber 1164 can be provided between the cluster chamber 1130 and the vacuum buffer chamber 1162. The carrier having a substrate can be routed from the processing chamber 1120-VIII through the transfer chamber 1182, through a cluster chamber 1130, through a transfer chamber 1164, into the vacuum buffer chamber 1162, as exemplarily shown in FIG. 6A. According to embodiments described herein, the substrate can be routed through one or more transfer chambers from the processing chamber to the vacuum buffer chamber.

From the vacuum buffer chamber 1162, the substrate can be routed through transfer chamber 1164 in which a cooling arrangement can be provided. After parking of the carrier adjacent the cooling arrangement for decreasing the temperature of the substrate carrier, the carrier can be further routed to the next processing chamber 1120. For example, as indicated in FIG. 6A by hatching the further transfer chamber 1182, a further cooling arrangement can be provided downstream of the further cooling arrangement.

According to some embodiments, which can be combined with other embodiments described herein, the vacuum processing system may beneficially include long transfer chambers having a length sufficient to accommodate substrate carriers and short transfer chambers having a length shorter than a substrate carrier. Parking a substrate carrier in front of a cooling arrangement is beneficially provided in a long transfer chamber such that a substrate carrier not moving while being parked in front of the cooling arrangement may not influence adjacent chambers, for example, a vacuum rotation chamber.

According to some embodiments, which can be combined with other embodiments described herein, the one or more transfer chambers may include a first transfer chamber between the first vacuum cluster chamber and the vacuum buffer chamber and a second transfer chamber between the first vacuum cluster chamber and the at least second vacuum cluster chamber. Yet further, additional or alternative modifications of the vacuum processing system have a second vacuum processing chamber, for example, the vacuum processing chamber downstream of the vacuum buffer chamber, has a mask alignment assembly for aligning a shadow mask to the substrate. Yet further, additionally or alternatively a second transfer chamber may have a first length extending between a first cluster chamber and a second cluster chamber, the first transfer chamber being sized to accommodate the substrate, and a third transfer chamber connected to the second cluster chamber, the second transfer chamber having a second length smaller than the first length.

According to embodiments of the present invention, the substrate transportation arrangement provided to route the substrate in orientation deviating from vertical by 15° or less can be provided. The vertical separate orientation is beneficial to have a reduced footprint. The substrate transportation arrangement can be provided to route the substrate through the first vacuum processing chamber, the second vacuum processing chamber, and the one or more transfer chambers.

According to one aspect, a vacuum processing system for OLED display manufacturing a large area substrate is provided. The system includes a metal deposition chamber having an evaporated of metallic material to be deposited on a stack on the large area substrate. The system includes a vacuum buffer chamber provided downstream of the metal deposition chamber in the vacuum processing system, the vacuum buffer chamber configured to store two or more carriers supporting large area substrates and a further deposition chamber downstream of the vacuum buffer chamber and having a further evaporator to deposit a material on the large area substrate, the further deposition chamber including a mask support for a shadow mask masking the large area substrates to deposit the material on regions corresponding to the display pixels. Further, the system includes a transfer chamber including a cooling assembly arranged adjacent to a carrier position to reduce the temperature of the carrier. Further aspects, advantages, features and embodiments of the present disclosure can be combined with such an embodiment.

According to some embodiments, further layers may be provided downstream of the vacuum buffer chamber 1162, for example in processing chambers 1120-IX and 1120-X.

After a final processing, a substrate can be moved via the buffer chamber 1112 to the vacuum swing module 1110, i.e. a substrate repositioning chamber. This is indicated by arrow 1193 in FIG. 6B. In the vacuum swing module the substrate is moved from the processing orientation, i.e. an essentially vertical orientation, to a substrate orientation corresponding to the interface with the factory, for example, a horizontal orientation.

Another embodiment, which may incorporate features of the embodiments described with respect to FIGS. 6A and 6B, is described with respect to FIGS. 7A and 7B. The vacuum processing system 1100 shown in FIGS. 7A and 7B includes a second vacuum swing module 1210, i.e. a second substrate repositioning chamber. Further, a second buffer chamber 1212 between a cluster chamber and the vacuum swing module can be provided. Accordingly, an exemplary substrate can be routed from one end of the in-line arrangement of cluster chambers to an opposing end of the in-line arrangement of cluster chambers. For example, the substrate can be loaded into the vacuum swing module 1110 and can be routed within the system essentially from one end, i.e. the left-hand side in FIG. 7A, to the opposing end, i.e. the right hand side in FIG. 7A. The substrate may be unloaded out of the vacuum processing system through vacuum swing module 1210, i.e. the vacuum swing module at the opposing end. According to some embodiments, the substrate traffic may switch between one row of processing chambers (see arrow 1032 in FIG. 4B) to the other row of processing chambers (see arrow 1034 in FIG. 4B) as, for example, indicated by arrow 1294 in FIG. 4B when transported from one processing chamber to the subsequent processing chamber. Thereafter, the substrate can be moved, as indicated by arrow 1296 in FIG. 4B, from the subsequent processing chamber in the other row of the vacuum processing system back to the first row of the vacuum processing system when moved to a yet further, subsequent processing chamber. Accordingly, according to some embodiments, an exemplary substrate may switch rows of the vacuum processing system or part of the vacuum processing system (see arrows 1032 and 1034 in FIG. 32) back and forth.

FIGS. 6A and 6B show transfer chambers, which are, for example, provided between cluster chambers such as vacuum rotation chambers. FIGS. 6A and 6B shows first transfer chambers 1182 and second transfer chambers 1184. Reducing the distance between adjacent or subsequent processing chambers as well as reducing the footprint of the vacuum processing system seems to suggest reduction of the lengths of the transfer chambers. It has surprisingly been found that a partial increase of the lengths of the transfer chambers improves the tact time of the vacuum processing system 1100. According to embodiments described herein, a vacuum processing system includes at least a first type of a transfer chamber, i.e. a first transfer chamber 1182, of a first length and the second type of the transfer chamber, i.e. a second transfer chamber 1184, having a second length smaller than the first length. According to embodiments of the present disclosure, a cooling arrangement for cooling a substrate carrier may beneficially be arranged in a first transfer chamber of the first length.

An “essentially vertical orientation” as used herein, for example, with respect to the substrate orientation, may be understood as an orientation with a deviation of 15° or less, 10° or less, particularly 5° or less from a vertical orientation, i.e. from the gravity vector. For example, an angle between a main surface of a substrate (or mask device) and the gravity vector may be between +10° and −10°, particularly between 0° and −5°. In some embodiments, the orientation of the substrate (or mask device) may not be exactly vertical during transport and/or during deposition, but slightly inclined with respect to the vertical axis, e.g. by an inclination angle from 0° and −5°, particularly between −1° and −5°. A negative angle refers to an orientation of the substrate (or mask device) wherein the substrate (or mask device) is inclined downward. A deviation of the substrate orientation from the gravity vector during deposition may be beneficial and might result in a more stable deposition process, or a facing down orientation might be suitable for reducing particles on the substrate during deposition. However, an exactly vertical orientation during transport and/or during deposition is also possible.

For increasing substrate sizes of large area substrates, wherein substrate sizes may typically increase in generations (GEN), vertical orientation is beneficial as compared to a horizontal orientation due to the reduced footprint of a vacuum processing system. An essentially vertical orientation of a deposition process on a large area substrate with a fine metal mask (FFM) is further unexpected in the sense that gravity acts along the surface of the fine metal mask in a vertical orientation. A pixel positioning and alignment in the micron range is more complicated for vertical orientation as compared to a horizontal orientation. Accordingly, concepts developed for horizontal vacuum deposition systems may not be transferred to vertical vacuum deposition systems for large area systems, particularly vacuum deposition systems utilizing a FFM.

The embodiments described herein can be utilized for inspecting large area coated substrates, e.g., for manufactured displays. The substrates or substrate receiving areas for which the apparatuses and methods described herein are configured can be large area substrates having a size of e.g. 1 m² or above. For example, a large area substrate or carrier can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented. For example, for OLED display manufacturing, half sizes of the above mentioned substrate generations, including GEN 6, can be coated by evaporation of an apparatus for evaporating material. The half sizes of the substrate generation may result from some processes running on a full substrate size, and subsequent processes running on half of a substrate previously processed.

The term “substrate” as used herein may particularly embrace substantially inflexible substrates, e.g., a wafer, slices of transparent crystal such as sapphire or the like, or a glass plate. However, the present disclosure is not limited thereto and the term “substrate” may embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.5 mm or below, wherein the flexibility of the substantially inflexible substrate is small in comparison to the flexible substrates.

A substrate may be made of any material suitable for material deposition. For instance, the substrate may be made of a material selected from the group consisting of glass (for instance soda-lime glass, borosilicate glass etc.), metal, polymer, ceramic, compound materials, carbon fiber materials, metal or any other material or combination of materials which can be coated by a deposition process.

According to yet further embodiments of modifications, which can be combined with other embodiments described herein, a vacuum processing system for large area substrates in a vertical or essentially vertical orientation as described herein can further include carriers for supporting substrates during transportation within the vacuum system. Particularly for large area substrates, glass breakage within the vacuum processing system may be reduced by utilizing carriers. Accordingly, the substrate may remain on a carrier for subsequent processing. For example, a substrate can be loaded on the carrier directly after or while entering the vacuum processing system and can be unloaded from the same carrier directly before or while leaving the vacuum processing system.

The vacuum processing system according to embodiments described herein may further include the substrate transportation arrangement configured for transporting substrates on carriers. The substrate transportation arrangement can include a carrier transportation system. As shown in FIG. 6A, carriers may be transported along transportation paths 1171, 1172, 1174, 1173 and may also be provided on transportation positions, such as transportation position 1175. The carrier transportation system may include a holding system, e.g. a magnetic levitation system, for lifting and holding the carriers, and a driving system for moving the carriers along tracks along a carrier transportation path. For example, the substrate transportation arrangement may include two substrate rotation positions in the vacuum rotation chamber.

In some embodiments, the substrate carrier is transported by a transportation system, which may include a magnetic levitation system. For example, a magnetic levitation system may be provided so that at least a part of the weight of the substrate carrier may be carried by the magnetic levitation system. The substrate carrier can be guided essentially contactlessly along the substrate carrier tracks through the vacuum processing system. A drive for moving the carrier along the substrate carrier tracks may be provided. Contactless levitation reduces particle generation in the vacuum processing system. This may be particularly advantageous for manufacturing of OLED devices.

According to yet further embodiments, which can be combined with other embodiments described herein, layer deposition on essentially vertically oriented large area substrates may beneficially be provided by deposition sources, for example, evaporation sources 1180 (see, e.g., FIG. 6A), therein the evaporation source can be provided as a line source. The line source can be moved along the surface of the substrate to deposit material on, for example, the rectangular large area substrate. According to yet further embodiments, two or more, for example, three line sources can be provided for a deposition source. According to some embodiments, which can be combined with other embodiments described herein, organic materials may be co-evaporated, wherein two or more organic materials form one material layer.

A deposition source, e.g. a vapor source configured for directing evaporated material toward one or more substrates, is typically arranged in a processing chamber or deposition module. For example, the deposition source may be movable along a source transportation track which may be provided in the processing chamber. The deposition source may linearly move along the source transportation track while directing the evaporated material toward one or more substrates.

In some embodiments, which may be combined with other embodiments described herein, a processing chamber or a deposition module may include two deposition areas, i.e. a first deposition area for arranging a first substrate and a second deposition area for arranging a second substrate. The first deposition area may be arranged opposite the second deposition area in the deposition module. The deposition source may be configured to subsequently direct evaporated material toward the first substrate arranged in the first deposition area and toward the second substrate arranged in the second deposition area. For example, an evaporation direction of the deposition source may be reversible, e.g. by rotating at least a part of the deposition source, e.g. by an angle of 180°.

FIG. 8 shows a top view including a cross-section of distribution pipes 706. FIG. 8 shows an embodiment having three distribution pipes 706, which are provided over an evaporator control housing 702. The distribution pipes 706 shown in FIG. 8 are heated by heating element 780. A cooled shield 782 is provided surrounding the distribution pipes 706. According to some embodiments, which can be combined with other embodiments described herein, one cooled shield can surround two or more distribution pipes 706. The organic materials, which are evaporated in an evaporation crucible are distributed in a respective one of the distribution pipes 706 and can exit the distribution pipe through outlets 712. Typically, a plurality of outlets are distributed along the length of the distribution pipe 706. According to embodiments described herein, a majority of the surface area of the distribution pipe and the surface area of the nozzles is covered with a cooled shield. Accordingly, the heat load can be reduced. Further, the distribution pipes 706 have a shape, for example, a triangular shape such that the surfaces of the distribution pipes, e.g. all three distribution pipes have an angle relative to a substrate surface that is 20° or larger. The outer surfaces of the distribution pipes are not parallel to the substrate surface to reduce heat load of heat radiation. Each distribution pipe is in fluid communication with the evaporation crucible (not shown in FIG. 8), and wherein the distribution shape has a cross-section perpendicular to the length of the distribution pipe, which is non-circular, and which includes an outlet side at which the one or more outlets are provided, wherein the width of the outlet side of the cross-section is 30% or less of the maximum dimension of the cross-section. The shape allows for the reduced heat radiation and allows for outlets of adjacent distribution pipes be close together, for example 60 mm or below.

FIG. 8 illustrates yet further embodiments described herein. Three distribution pipes 706 are provided. An evaporator control housing 702 is provided adjacent to the distribution pipes and connected thereto via a thermal insulator 703. As described above, the evaporator control housing, configured to maintain atmospheric pressure therein, is configured to house at least one element selected from the group consisting of a switch, a valve, a controller, a cooling unit, a cooling control unit, a heating control unit, a power supply, and a measurement device. In addition to the cooled shield 782, the cooled shield 784 is provided, which has sidewalls 786. The cooled shield 784 and the sidewalls 786 provide a U-shaped cooled shield to reduce the heat radiation towards the deposition area, i.e. a substrate and/or a mask. As further shown in FIG. 8A, shaper shields 790 are provided, for example, attached to the cooled shield or as a part of the cooled shield. According to some embodiments, the shaper shields 790 can also be cooled to further reduce the heat load emitted towards the deposition area.

A plurality of shields 783 are provided at the outlet sidewall of the evaporation source. For example, at least 5 or even at least 7 shields are provided at the outlet side of the evaporation tube. The plurality of shields can be provided as stacks of shields, e.g. wherein the shields are distant from each other by 0.1 mm to 3 mm.

In light of the above, the heat load on a substrate can be reduced by heat shields, such as stacked heat shields, cooling shields, such as actively cooled shields, covering portions of a nozzle outlet by one or more shields to reduce heat impact on the substrate, and/or the shape of the distribution pipes.

FIG. 9 illustrates a flowchart of a method of operating a vacuum processing system according to embodiments of the present disclosure. As illustrated by box 902, a material layer, such as a metal layer, is deposited on a substrate during, for example, a first tact time period. A carrier supporting the substrate is parked (see box 904) in a vacuum buffer chamber during one or more second time periods subsequent to the first tact time period. Further, as indicated by box 906, the carrier is cooled in a transfer chamber adjacent a cooling assembly during at least a portion of a third tact time period subsequent to the one or more second tact time periods.

As indicated by box 908, a masked deposition is provided after the substrate temperature has been reduced due to parking in the vacuum buffer chamber.

While the foregoing is directed to embodiments of the disclosure, other and further embodiments of the disclosure may be devised without departing from the basic scope thereof, and the scope thereof is determined by the claims that follow.

1. A vacuum processing system for routing a carrier with a substrate to be processed, comprising:
a first vacuum processing chamber for processing the substrate on the carrier;
a vacuum buffer chamber providing a processing time delay for the substrate;
a second vacuum processing chamber for masked deposition of a material layer on the substrate; and
one or more transfer chambers for routing the carrier from the first vacuum chamber to the vacuum buffer chamber and for routing the carrier from the vacuum buffer chamber to the second vacuum chamber.

2. The vacuum processing system according to claim 1, wherein the vacuum buffer chamber provides a first-in-first-out stack for received carriers.

3. The vacuum processing system according to claim 1, wherein the vacuum buffer chamber is configured to buffer four or more substrate carriers.

4. The vacuum processing system according to claim 1, wherein the one or more transfer chambers comprise:
a first vacuum cluster chamber directing a carrier from a first transport direction in the vacuum processing system to a second transport direction in the vacuum processing system.

5. The vacuum processing system according to claim 4, further comprising:
at least a second vacuum cluster chamber directing a carrier from a first transport direction in the vacuum processing system to a second transport direction in the vacuum processing system.

6. The vacuum processing system according to claim 5, wherein the one or more transfer chambers further comprise:
a first transfer chamber between the first vacuum cluster chamber and the vacuum buffer chamber; and
a second transfer chamber between the first vacuum cluster chamber and the at least second vacuum cluster chamber.

7. The vacuum processing system according to claim 6, wherein at least one of the first transfer chamber and the second transfer chamber comprises:
a cooling assembly arranged adjacent to a carrier position to reduce a temperature of the carrier.

8. The vacuum processing system according to claim 7, wherein the cooling assembly includes one or more cooled surfaces having an area with conduits for cooling fluid.

9. The vacuum processing system according to claim 1, wherein the second vacuum chamber has a mask alignment assembly for aligning a shadow mask to the substrate.

10. The vacuum processing system according to claim 1, wherein the second transfer chamber has a first length extending between the first cluster chamber and the second cluster chamber, the first transfer chamber being sized to accommodate the substrate;
the system further comprising:
a third transfer chamber connected to the second cluster chamber, the second transfer chamber having a second length smaller than the first length.

11. The vacuum processing system according to claim 1, further comprising:
a substrate transportation arrangement provided to route the substrate in an orientation deviating from vertical by 15° or less through the first vacuum processing chamber, the second vacuum processing chamber, and the one or more transfer chambers.

12. A vacuum processing system for OLED display manufacturing on a large area substrate, comprising:
a metal deposition chamber having an evaporator for metallic material to be deposited on a layer stack on the large area substrate;
a vacuum buffer chamber provided downstream of the metal deposition chamber in the vacuum processing system, the vacuum buffer chamber configured to store two or more carriers supporting large area substrates;
a further deposition chamber downstream of the vacuum buffer chamber and having a further evaporator to deposit a material on the large area substrate, the further deposition chamber including a mask support for a shadow mask masking the large area substrates to deposit the material on regions corresponding to display pixels; and
a transfer chamber including a cooling assembly arranged adjacent to a carrier position to reduce the temperature of the carrier.

13. A method of operating a vacuum processing system, comprising:
depositing a material layer on a substrate during a first tact time period;
parking a carrier supporting the substrate in a vacuum buffer chamber during one or more second tact time periods subsequent to the first tact time period; and
cooling the carrier in a transfer chamber adjacent to a cooling assembly during at least a portion of a third tact time period subsequent to the one or more second tact time periods.

14. The method of claim 13, wherein the substrate is parked in a vacuum buffer chamber during at least 3 tact time periods.

15. The method of claim 13, wherein a carrier temperature is increased during the parking and the carrier temperature is reduced during the cooling.
